(19) United States
(12) Patent Application Publication
(10) Pub. No.: US 2014/0016410 A1
(43) Pub. Date: Jan. 16, 2014

(54) MEMORY DEVICE AND METHOD ADJUSTING READ VOLTAGE ACCORDING TO VARYING THRESHOLD VOLTAGE DISTRIBUTIONS

(71) Applicant: SAMSUNG ELECTRONICS CO., LTD., Suwon-si (KR)

(72) Inventors: Myung-hoon Choi, Suwon-si (KR); Ki-tae Park, Seongnam-si (KR); Jae-yong Jeong, Yongin-si (KR)

(73) Assignee: SAMSUNG ELECTRONICS CO., LTD., Suwon-si (KR)

(21) Appl. No.: 13/887,830

(22) Filed: May 6, 2013

(30) Foreign Application Priority Data
Jul. 10, 2012 (KR) 10-2012-0075172

(51) Int. Cl. G11C 16/26

(52) U.S. Cl. CPC G11C 16/26
USPC 365/185.03

(57) ABSTRACT

A memory device comprises a memory cell that is in one of an erase state and first through N-th program states (N>2). The memory device can be read by determining a first read voltage between the erase state and the first program state based on variations of respective threshold voltage distributions of the erase state and the first program state, and determining one among second through N-th read voltages based on variations in respective threshold voltage distributions of two adjacent program states among the first through N-th program states, and determining remaining read voltages among the second through N-th read voltages based on the one read voltage.

### CROSS-REFERENCE TO RELATED APPLICATION

This application claims priority, under 35 U.S.C. §119, to Korean Patent Application No. 10-2012-0075172 filed on Jul. 10, 2012, the subject matter of which is hereby incorporated by reference.

### BACKGROUND OF THE INVENTION

The inventive concept relates generally to electronic data storage technologies. More particularly, certain embodiments of the inventive concept relate to memory devices and methods that adjust read voltages according to varying threshold voltage distributions of memory cells.

There is a general demand, in many fields of electronics, to produce components with reduced size and higher performance. In the field of electronic data storage technologies, in particular, there is a demand for memory devices having smaller memory cells, higher storage capacity, faster access time, and lower power consumption, among other things.

In an effort to produce nonvolatile memory devices with relatively small size and high storage capacity, researchers have developed technologies and techniques for storing more than one bit of data per memory cell. In general, a memory device storing more than one bit of data per memory cell can be referred to as a multi-level cell (MLC) memory device. One drawback of storing more than one bit of data per memory cell is that it can reduce the reliability of the memory cells. For instance, in a flash memory device, storing more than one bit of data per memory cell may reduce the margins between adjacent threshold voltage distributions, requiring tighter operating margins and increasing the probability of read or program errors. Accordingly, as researchers continue to develop MLC memory devices, there is a related need to develop techniques and technologies to control the reliability of those devices.

### SUMMARY OF THE INVENTION

In an embodiment of the inventive concept, a method is provided for reading a memory device comprising a memory cell that is in one of an erase state and first through N-th program states (N>2). The method comprises determining a first read voltage between the erase state and the first program state based on variations of respective threshold voltage distributions of the erase state and the first program state, and determining one among second through N-th read voltages based on variations in respective threshold voltage distributions of two adjacent program states among the first through N-th program states, and determining remaining read voltages among the second through N-th read voltages based on the one read voltage.

In another embodiment of the inventive concept, a memory device comprises a memory cell array comprising a plurality of memory cells each being in one among an erase state and first through N-th program states (N>2), and a read voltage controlling unit that determines a first read voltage between the erase state and the first program state based on respective variations of threshold voltage distributions of the erase state and the first program state, determines one among second through N-th read voltages based on respective variations in threshold voltage distributions of two adjacent program states among the first through N-th program states, and determines remaining read voltages among the second through N-th read voltages based on the one read voltage.

In another embodiment of the inventive concept, a method is provided for reading a memory device comprising a memory cell that is in one of an erase state and first through N-th program states (N>2). The method comprises determining one among first through N-th read voltages for the memory cell based on data read from the memory device, and determining additional read voltages among the second through N-th read voltages based on the one read voltage.

These and other embodiments of the inventive concept can potentially reduce a read failure rate of a memory device or system by controlling a read voltage according to variations in threshold voltage distributions of memory cells.

### BRIEF DESCRIPTION OF THE DRAWINGS

The drawings illustrate selected embodiments of the inventive concept. In the drawings, like reference numbers indicate like features.

FIG. 1 is a block diagram of a memory system according to an embodiment of the inventive concept.

FIG. 2 is a block diagram of a memory device in the memory system of FIG. 1 according to an embodiment of the inventive concept.

FIG. 3 illustrates a memory cell array of the memory device of FIG. 2 according to an embodiment of the inventive concept.

FIG. 4 is a circuit diagram of a memory block of the memory cell array of FIG. 3 according to an embodiment of the inventive concept.

FIG. 5 is a cross-sectional view of a memory cell of the memory block of FIG. 4 according to an embodiment of the inventive concept.

FIG. 6A is a graph illustrating threshold voltage distributions of memory cells storing 2-bit data.

FIG. 6B is a graph illustrating degradation of the threshold voltage distributions of FIG. 6A.

FIG. 7A is a graph illustrating threshold voltage distributions of memory cells storing 3-bit data.

FIG. 7B is a graph illustrating degradation of the threshold voltage distributions of FIG. 7A.

FIG. 8 is a flowchart illustrating a method of reading a memory device according to an embodiment of the inventive concept.

FIG. 9 is a flowchart illustrating an operation determining first through N-th read voltages in the method of FIG. 8 according to an embodiment of the inventive concept.

FIG. 10 is a flowchart illustrating an operation determining second through N-th read voltages in the operation of FIG. 9 according to an embodiment of the inventive concept.

FIG. 11 is a flowchart illustrating an operation determining remaining read voltages used in the operation of FIG. 10 according to an embodiment of the inventive concept.

FIG. 12 is a graph illustrating read voltages that have been determined by the operations of FIGS. 9 through 11 for memory cells having the threshold voltage distributions of FIG. 6B.

FIG. 13 is a graph illustrating read voltages that have been determined by the operations of FIGS. 9 through 11 for memory cells having the threshold voltage distributions of FIG. 7B.

FIG. 14 is a flowchart illustrating an operation determining second through N-th read voltages in the operation of FIG. 9 according to another embodiment of the inventive concept.

FIG. 15 is a graph showing variations in read voltages according to program/erase cycle values.

FIG. 16 is a graph of read voltages that have been determined by the operation of FIG. 14 for memory cells having the threshold voltage distributions of FIG. 7B.

FIG. 17 is a flowchart illustrating an operation determining second through N-th read voltages in the operation of FIG. 9 according to another embodiment of the inventive concept.

FIG. 18 is a table illustrating a pre-defined table (PDT) used in the operation of FIG. 17 according to an embodiment of the inventive concept.

FIG. 19A is a graph showing a read order for a first page in the operations of FIGS. 8 through 11, FIG. 14, and FIG. 17.

FIG. 19B is a graph showing a read order for a second page in the operations of FIGS. 8 through 11, FIG. 14, and FIG. 17.

FIG. 19C is a graph showing a read order for a third page in the operations of FIGS. 8 through 11, FIG. 14, and FIG. 17.

FIG. 20 is a block diagram of a memory system according to another embodiment of the inventive concept.

FIG. 21 is a block diagram of a memory device in the memory system of FIG. 20 according to another embodiment of the inventive concept.

FIG. 22 is a block diagram of a computing system incorporating the memory system of FIG. 1 or 20 according to an embodiment of the inventive concept.

### DETAILED DESCRIPTION

Embodiments of the inventive concept are described below with reference to the accompanying drawings. These embodiments are provided as teaching examples and should not be construed to limit the scope of the inventive concept.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. The terms “comprises” and/or “comprising,” or “includes” and/or “including” when used in this specification, indicate the presence of stated features but do not preclude the presence or addition of one or more other features.

The terms first, second, third etc. may be used herein to describe various features, but the described features should not be limited by these terms. Rather, these terms are used merely to distinguish between different features. Thus, a first feature could alternatively be termed a second feature and vice versa without materially changing the meaning of the relevant description.

Unless otherwise defined, all terms (including technical and scientific terms) used herein have the same meaning as commonly understood by one of ordinary skill in the art. Terms such as those defined in commonly used dictionaries should be interpreted as having a meaning that is consistent with their meaning in the context of the relevant art and will not be interpreted in an idealized or overly formal sense unless expressly so defined herein.

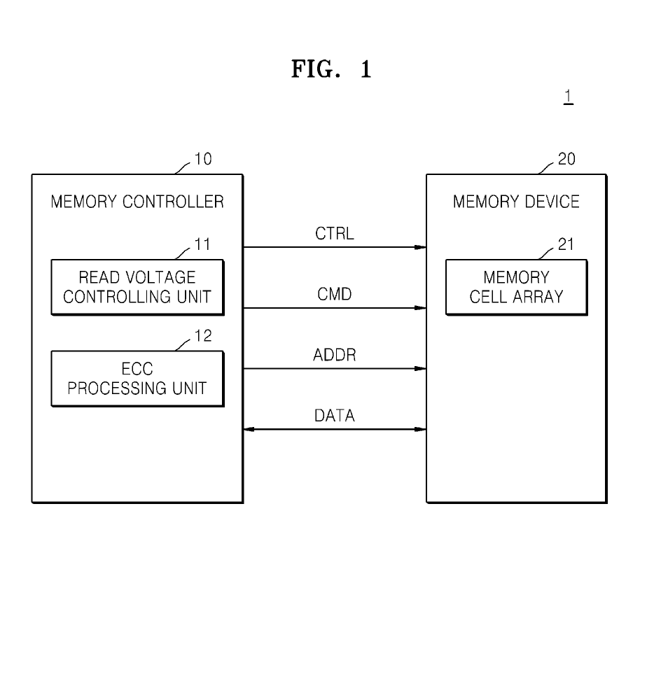

FIG. 1 is a block diagram of a memory system 1 according to an embodiment of the inventive concept.

Referring to FIG. 1, memory system 1 comprises a memory controller 10 and a memory device 20. Memory controller 10 performs operations to control memory device 20. For example, memory controller 10 may control program, read, and erase operations of memory device 20 by supplying address signals ADDR, command signals CMD, and control signals CTRL to memory device 20.

Memory device 20 comprises a memory cell array 21. Memory cell array 21 comprises a plurality of memory cells (not shown) disposed at intersections of wordlines and bitlines. In certain embodiments described below, the memory cells are assumed to be flash memory cells, and memory cell array 21 is a NAND flash memory cell array or a NOR flash memory cell array, although the inventive concept is not limited to flash memory or specific memory configurations. In alternative embodiments, for example, memory cell array 21 could be a resistive memory, such as a resistive random access memory (RRAM), a phase change RAM (PRAM), or a magnetic RAM (MRAM).

Memory controller 10 comprises a read voltage controlling unit 11 and an error correction code (ECC) processing unit 12. Memory controller 10 may control levels of read voltages for reading data from the plurality of memory cells, and it may control memory device 20 by outputting the controlled read voltages.

Read voltage controlling unit 11 controls levels of read voltages for reading memory device 20, i.e., for reading data stored in memory cells disposed in memory cell array 21, based on data DATA received from memory device 20. This control is implemented by supplying control signals CTRL to memory device 20. Read voltage controlling unit 11 controls levels of read voltages based on threshold voltages of the memory cells that have varied due to an external stimulus and/or wear and may otherwise lead to an increased raw bit error rate (RBER) of the memory device.

ECC processing unit 12 checks whether there is a read error in the data DATA read from memory device 20 and may correct the read error. To do so, ECC processing unit 12 may compare parity data generated and stored when the data DATA is programmed, with parity data generated when the data DATA is read, detect an error bit of the data DATA, and perform an XOR operation on the detected error bit to correct the read error.

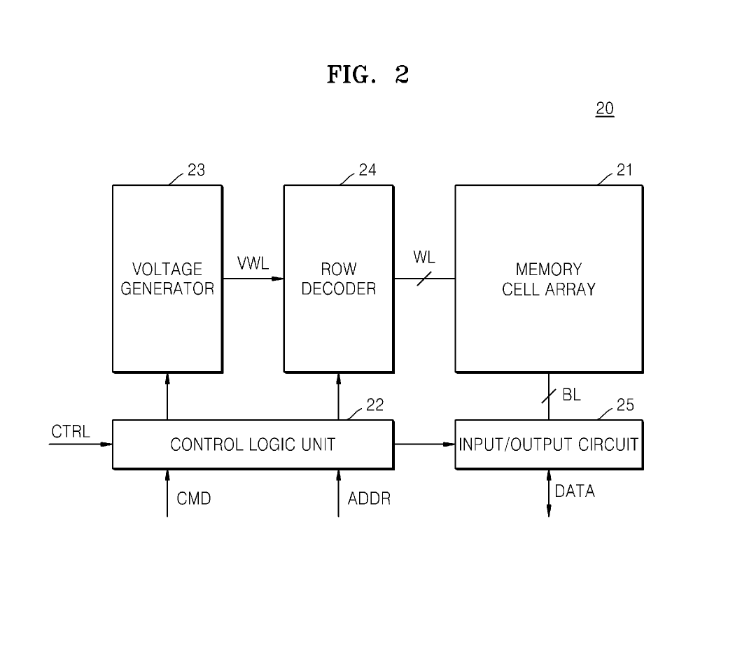

FIG. 2 is a block diagram of memory device 20 of memory system 1 of FIG. 1 according to an embodiment of the inventive concept.

Referring to FIG. 2, memory device 20 comprises memory cell array 21, a control logic unit 22, a voltage generator 23, a row decoder 24, and an input/output circuit 25.

Control logic unit 22 outputs various control signals for writing data DATA into memory cell array 21 or for reading the data DATA from memory cell array 21 based on command signals CMD, address signals ADDR, and control signals CTRL received from memory controller 10. In this case, the control signals output from control logic unit 22 may be transferred to voltage generator 23, row decoder 24, and input/output circuit 25.

Voltage generator 23 generates driving voltages VWL for driving a plurality of wordlines WL based on control signals CTRL received from control logic unit 22. Driving voltages VWL may be, for instance, write voltages (or program voltages), read voltages, erase voltages, or pass voltages.

Row decoder 24 activates some of the plurality of wordlines WL based on a row address. During a read operation, row decoder 24 applies a read voltage to a selected wordline WL and applies a pass voltage to unselected wordlines WL. In addition, during a write operation, row decoder 24 applies a write voltage to the selected wordline WL and applies a pass voltage to the unselected wordline WL.

Input/output circuit 25 is connected to memory cell array 21 via a plurality of bit lines BL. During the read operation, input/output circuit 25 functions as a sense amplifier and outputs data stored in memory cell array 21. In addition, during the write operation, input/output circuit 25 functions as a write driver and inputs data to be stored to memory cell array 21.

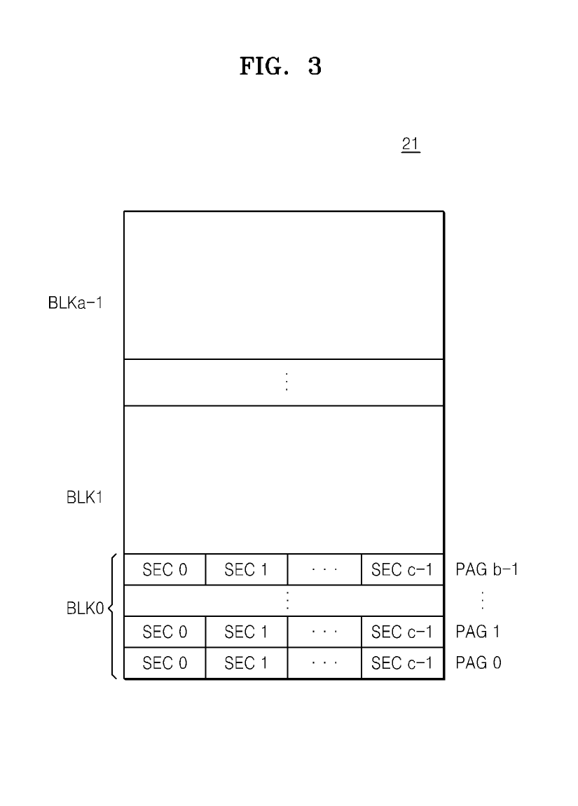

FIG. 3 illustrates a more detailed version of memory cell array 21 according to an embodiment of the inventive concept.

Referring to FIG. 3, memory cell array 21 may be a flash memory cell array. In this case, memory cell array 21 comprises a (a>1) blocks BLK0 to BLKa-1, and each of the a blocks BLK0 to BLKa-1 comprises b (b>1) pages PAG0 to PAGb-1, and each of the b pages PAG0 to PAGb-1 comprises c (c>1) sectors SECO to SECc-1. In FIG. 3, for convenience, the b pages PAG0 to PAGb-1 and the c sectors SECO to SECc-1 are disposed only on block BLK0. However, other blocks BLK1 to BLKa-1 may have the same structure as block BLK0.

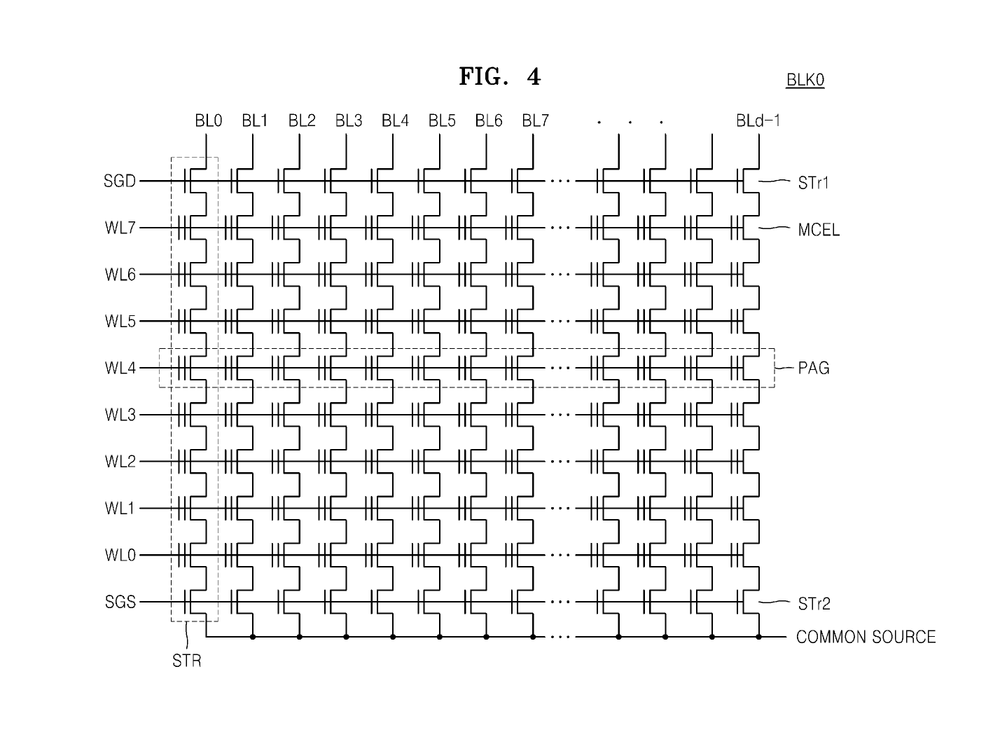

FIG. 4 is a circuit diagram of memory block BLK0 of memory cell array 21 according to an embodiment of the inventive concept. In the example of FIG. 4, memory cell array 21 is a memory cell array of a NAND flash memory. Each of blocks BLK0 to BLKa-1 in FIG. 3 may be implemented as illustrated in FIG. 4.

Referring to FIG. 4, each of blocks BLK0 to BLKa-1 comprises d (d>1) strings STR in which 8 memory cells MCEL are connected in series in directions of bitlines BL0 to BLd-1. Each of the d strings STR comprises a drain selection transistor Str1 and a source selection transistor Str2, which are connected to ends of the 8 memory cells MCEL connected in series.

A NAND flash memory device having the structure of FIG. 4 performs erase operations in units of blocks and performs program operations in units of pages PAG corresponding to wordlines WL0 to WL7. FIG. 4 illustrates an example where 8 pages PAG corresponding to 8 wordlines WL0 to WL7 are disposed on one block. However, blocks BLK0 to BLKa-1 of memory cell array 21 may comprise other numbers of pages and/or memory cells. In addition, memory device 20 of FIGS. 1 and 2 may comprise a plurality of memory cell arrays that perform the same operation as or have the same structure as that of memory cell array 21 described above.

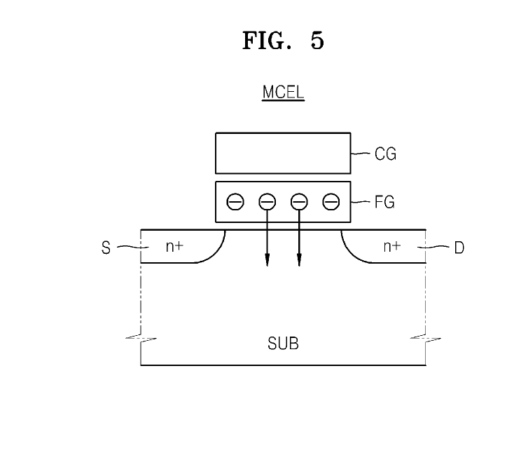

FIG. 5 is a cross-sectional view of memory cell MCEL of memory block BLK0 of FIG. 4 according to an embodiment of the inventive concept.

Referring to FIG. 5, a source region S and a drain region D are formed on a substrate SUB, and a channel region is formed between source region S and drain region D. A floating gate FG is formed above the channel region, and an insulating layer, such as a tunneling insulating layer, is disposed between the channel region and floating gate FG. A control gate CG is formed above floating gate FG, and an insulating layer, such as a blocking insulating layer, is disposed between floating gate FG and control gate CG. Voltages for program, erase, and read operations of memory cell MCEL are applied to substrate SUB, source region S, drain region D, and control gate CG.

In the flash memory device, data stored in memory cell MCEL is read by distinguishing a threshold voltage state of memory cell MCEL, or the threshold voltage distribution to which it belongs. The threshold voltage state of memory cell MCEL is determined by the amount of electrons stored in floating gate FG. As the number of electrons stored in floating gate FG increases, the threshold voltage Vth of memory cell MCEL increases.

The electrons stored in floating gate FG of memory cell MCEL may leak for various reasons in a direction of arrows shown in FIG. 5 and thus, threshold voltage Vth of memory cell MCEL may vary. For example, the electrons stored in floating gate FG may leak due to wearing of memory cell MCEL. In detail, when an access operation, such as a program, erase, or read operation of memory cell MCEL, is repeatedly performed, the insulating layer between the channel region and floating gate G may deteriorate. Thus, the electrons stored in floating gate FG may leak. In addition, the electrons stored in floating gate FG may leak due to high-temperature stress or a difference in temperatures when the programming/read operation is performed.

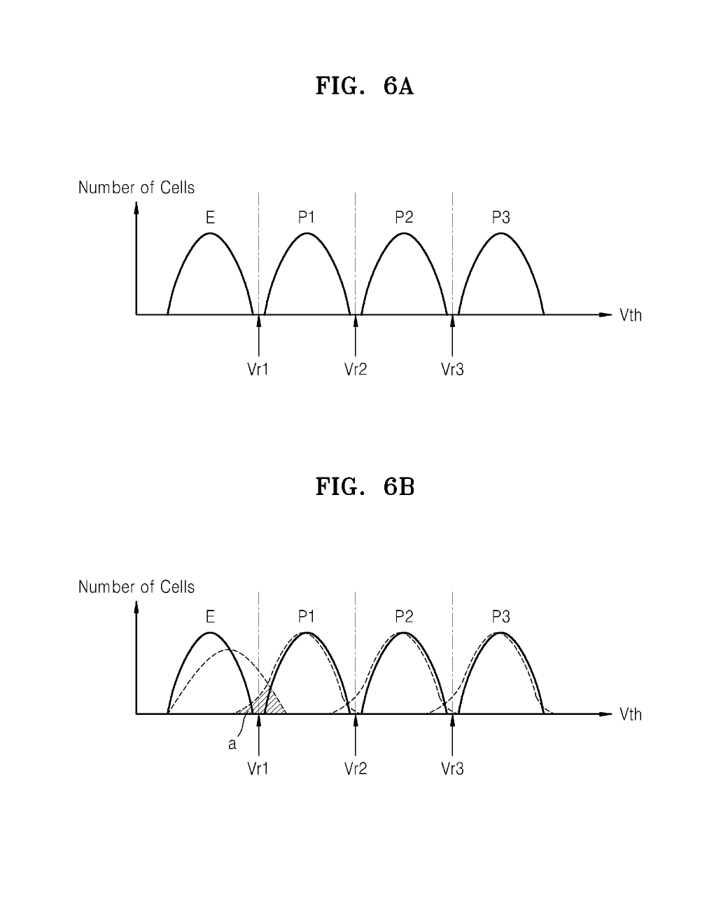

FIG. 6A is a graph illustrating threshold voltage distributions of memory cells storing 2-bit data in memory device 20.

Referring to 6A, the horizontal axis represents threshold voltages Vth, and the vertical axis represents the number of memory cells. Where memory cell MCEL is a 2-bit multi-level cell, memory cell MCEL may be in one of an erase state E, a first program state P1, a second program state P2, and a third program state P3. In a multi-level cell, a distance between adjacent threshold voltage distributions is typically smaller than in a single level cell. Thus, in the multi-level cell, errors may occur due to small variations of threshold voltages Vth.

A first read voltage Vr1 is at a voltage level between respective threshold voltage distributions of memory cells MCEL in erase state E and memory cells MCEL in first program state P1. A second read voltage Vr2 is at a voltage level between respective threshold voltage distributions of memory cells MCEL in first program state P1 and memory cells MCEL in second program state P2. A third read voltage Vr3 is at a voltage level between respective threshold voltage distributions of memory cells MCEL in second program state P2 and memory cells MCEL in third program state P3.

Where first read voltage Vr1 is applied to control gate CG of memory cell MCEL, memory cell MCEL in erase state E is turned on and memory cell MCEL in first program state P1 is turned off. Where memory cell MCEL is turned on, current flows through memory cell MCEL, and where memory cell MCEL is turned off, current does not flow through memory cell MCEL. Thus, data stored in memory cell MCEL may be determined by whether memory cell MCEL is turned on. In this case, it may be determined that data ‘1’ is stored in memory cell MCEL in erase state E and data ‘0’ is stored in memory cell MCEL in first program state P1.

FIG. 6B is a graph illustrating degradation of the threshold voltage distributions of FIG. 6A.

Referring to FIG. 6B, a solid line represents initial threshold voltage distributions of memory cells MCEL, and a dotted line represents threshold voltage distributions of memory cells MCEL that have varied due to an external stimulus and/or wear. In FIG. 6B, read errors may occur in memory cells MCEL within a hatched portion “a”. Thus, the reliability of memory device 20 may be lowered.

As an example, where a read operation is performed on memory device 20 using first read voltage Vr1, even if memory cells MCEL within the hatched portion are programmed in first program state P1, memory cells MCEL may be determined to be in erase state E due to a reduction in threshold voltages Vth. Thus, errors occur in the read operation, and the reliability of memory device 20 may be diminished.

In FIG. 6B, in threshold voltage distributions corresponding to first through third program states P1, P2, and P3, threshold voltages Vth are decreased. More specifically, each threshold voltage distribution of first through third program states P1, P2, and P3 is moved to the left side. A left end of each threshold voltage distribution of first through third program states P1, P2, and P3 is moved to the left, and a right end thereof is moved to the right. On the other hand, in the threshold voltage distribution of erase state E, threshold voltages Vth are increased. In addition, a value by which threshold voltages Vth of memory cells MCEL in erase state E are increased is larger than a value by which threshold voltages Vth of memory cells MCEL in first program state P1 are decreased. Thus, second and third read voltages Vr2 and Vr3 are controlled to be decreased to reflect variation in threshold voltage distributions of memory cells MCEL, whereas the first read voltage Vr1 is controlled to be increased to reflect a variation in the threshold voltage distributions of memory cells MCEL.

Where threshold voltage distributions of memory cells MCEL have varied, a variation in one among first through third read voltages Vr1 to Vr3 may be determined based on a variation in threshold voltage distributions of at least one among first through third program states P1 to P3, and the determined variation may be applied to remaining read voltages. For example, after a variation in one among the first through third read voltages Vr1 to Vr3 is determined, the magnitude of the variation may be used as a fixed value. However, as described above, unlike the second and third read voltages Vr2 and Vr3, first read voltage Vr1 is typically increased due to the variation of threshold voltage distributions rather than by a fixed value. Thus, the variation in the first read voltage Vr1 is generally required to be determined independently.

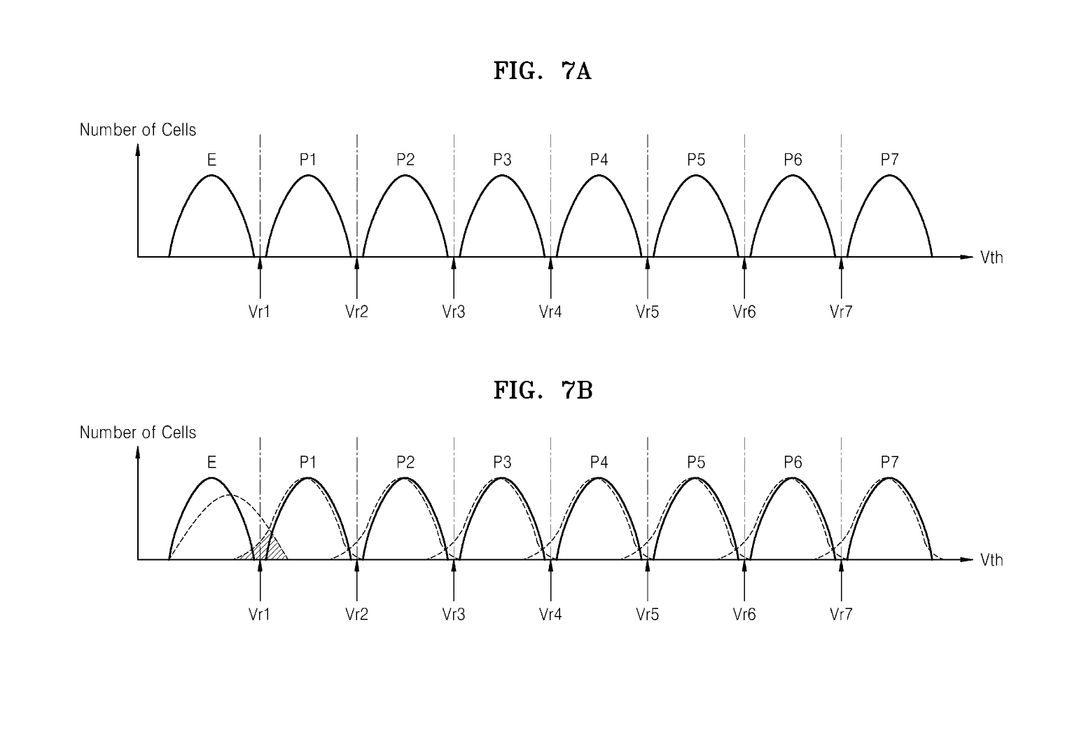

FIG. 7A is a graph illustrating threshold voltage distributions of memory cells storing 3-bit data in memory device 20.

Referring to FIG. 7A, the horizontal axis represents threshold voltages Vth, and the vertical axis represents the number of memory cells MCEL. Where memory cells are 3-bit multi-level cells, they may be in one state among an erase state E, a first program state P1, a second program state P2, a third program state P3, a fourth program state P4, a fifth program state P5, a sixth program state P6, and a seventh program state P7. In a multi-level cell, because a distance between threshold voltage distributions is smaller than in a single level cell, in the multi-level cell, errors may occur due to small variations of threshold voltages Vth.

A first read voltage Vr1 is at a voltage level between distribution of memory cells MCEL in erase state E and distribution of memory cells MCEL in first program state P1. A second read voltage Vr2 is at a voltage level between distribution of memory cells MCEL in first program state P1 and distribution of memory cells MCEL in second program state P2. A third read voltage Vr3 is at a voltage level between a threshold voltage distribution of memory cells MCEL in second program state P2 and a threshold voltage distribution of memory cells MCEL in third program state P3. A fourth read voltage Vr4 is at a voltage level between a threshold voltage distribution of memory cells MCEL in third program state P3 and a threshold voltage distribution of memory cells MCEL in fourth program state P4. A fifth read voltage Vr5 is at a voltage level between a threshold voltage distribution of memory cells MCEL in fourth program state P4 and a threshold voltage distribution of memory cells MCEL in fifth program state P5. A sixth read voltage Vr6 is at a voltage level between a threshold voltage distribution of memory cells MCEL in fifth program state P5 and a threshold voltage distribution of memory cells MCEL in sixth program state P6. A seventh read voltage Vr7 is at a voltage level between a threshold voltage distribution of memory cells MCEL in sixth program state P6 and a threshold voltage distribution of memory cells MCEL in seventh program state P7.

FIG. 7B is a graph illustrating degradation of the threshold voltage distributions of FIG. 7A.

Referring to FIG. 7B, a solid line represents initial distribution of memory cells MCEL, and a dotted line represents distribution of memory cells MCEL that have varied due to an external stimulus and/or wear. In FIG. 7B, read errors may occur in memory cells MCEL within a hatched portion. Thus, the reliability of memory device 20 may be lowered.

In FIG. 7B, in distributions of first through seventh program states P1 to P7, threshold voltages Vth are decreased. In particular, each distribution of the first through seventh program states P1 to P7 is moved to the left. A left end of each distribution of the first through seventh program states P1 to P7 is moved to the left, and a right end thereof is moved to the right. On the other hand, in distribution of erase state E, threshold voltages Vth are increased. In addition, a value by which threshold voltages Vth of memory cells MCEL in erase state E are increased is larger than a value by which threshold voltages Vth of memory cells MCEL in first program state P1 are decreased. Thus, second through seventh read voltages Vr2 to Vr3 are controlled to be decreased to reflect variation in threshold voltage distributions of memory cells MCEL, whereas the first read voltage Vr1 are controlled to be increased to reflect variation in threshold voltage distributions of memory cells MCEL.

Where threshold voltage distributions of memory cells MCEL are varied, a variation in one among the first through seventh read voltages Vr1 to Vr7 may be determined based on a variation in threshold voltage distributions of at least one among the first through seventh program states P1 to P7, and the determined variation may be applied to the remaining read voltages. For example, after a variation in one among first through seventh read voltages Vr1 to Vr7 is determined, the magnitude of the variation may be used as a fixed value. However, as indicated above, unlike second through seventh read voltages Vr2 to Vr7, first read voltage Vr1 is typically increased due to the variation in threshold voltage distributions. In other words, it is typically determined independently.

Where data is read from memory device 20, an RBER varies according to a level of a read voltage. A desired level of the read voltage may be determined based on the shape of threshold voltage distribution of memory cells MCEL. Thus, as the threshold voltage distributions of memory cells MCEL varies, a desired voltage level of the read voltage required for reading data from memory device 20 may vary accordingly.

The desired level of the read voltage is determined by estimating a variation in the threshold voltage distributions of memory cells MCEL and compensating for the estimated variation in the threshold voltage distributions of memory cells MCEL by varying the level of the read voltage. In this case, to effectively determine the desired level of the read voltage, a variation in the threshold voltage distributions of memory cells MCEL may be estimated based on a relatively small amount of measurement data.

Examples where memory cell MCEL is a 2-bit multi-level cell or a 3-bit multi-level cell have been described above with reference to FIGS. 6A, 6B, 7A, and 7B. However, aspects of the inventive concept are not limited thereto, and memory cell MCEL of FIG. 5 may be a multi-level cell that is programmed with 4 bits or more. In addition, memory device 20 of FIGS. 1 and 2 comprises memory cells MCEL that are programmed with a different number of bits. Furthermore, memory device 20 of FIGS. 1 and 2 comprises both a single level cell that is programmed with 1 bit and a multi-level cell.

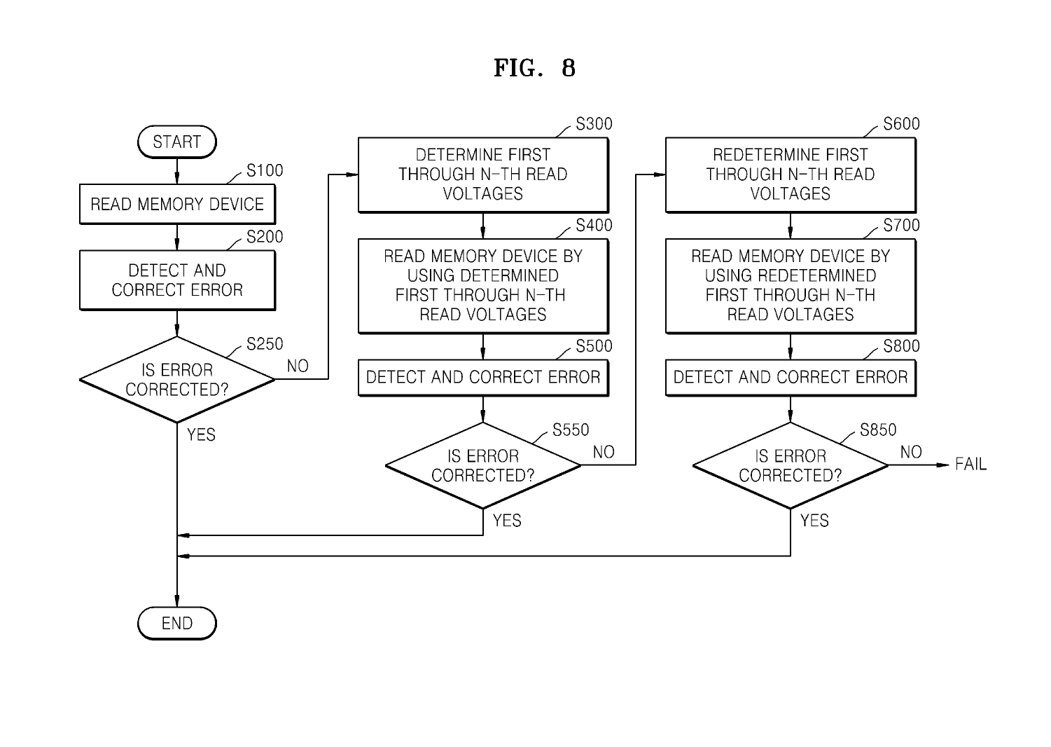

FIG. 8 is a flowchart illustrating a method of reading a memory device according to an embodiment of the inventive concept. The method can be performed, for instance, by a memory system described above in relation to FIGS. 1 through 5. For convenience, the method will be described with reference to a 3-bit multi-level cell.

Referring to FIG. 8, in operation S100, a memory controller reads the memory device. The memory controller reads data stored in the memory cell array of the memory device by applying first through seventh read voltages Vr1 to Vr7 to the memory device. Hereinafter, the first through seventh read voltages Vr1 to Vr7 are referred to as “initial” first through seventh read voltages.

Thereafter, in operation S200, the memory controller detects an error in the data read from the memory device and corrects the detected error. If no error is detected in the data, the method of reading the memory device is terminated. Otherwise, the method proceeds to operation S250. In operation S250, the memory controller determines whether the detected error has been corrected. If the detected error has been corrected, the method is terminated. Otherwise, the method proceeds to operation S300.

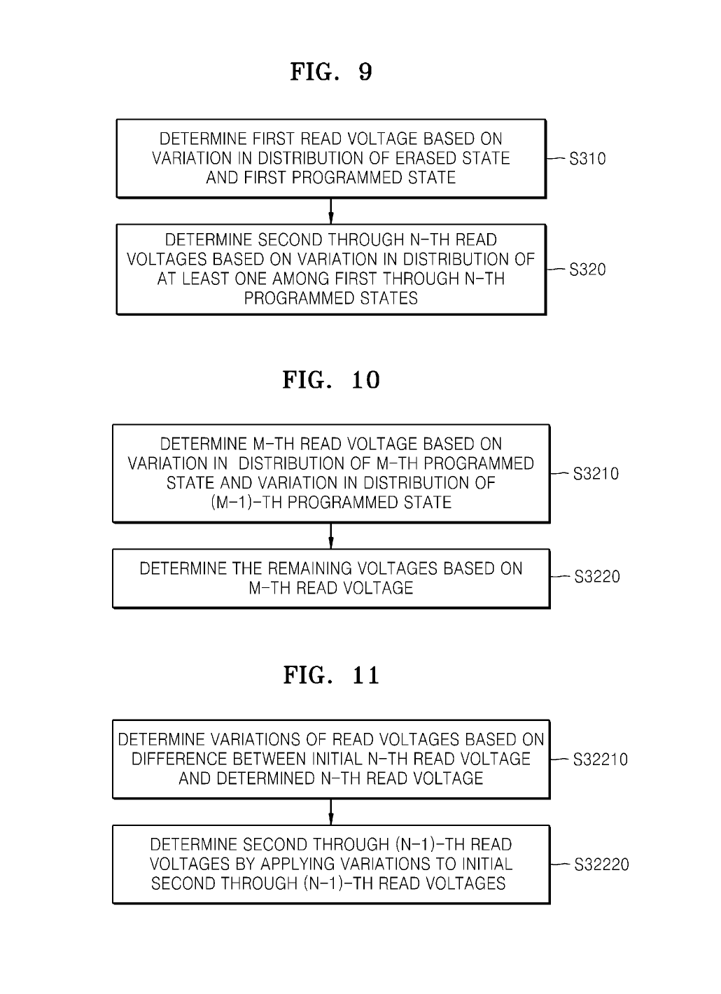

In operation S300, a read voltage controlling unit determines first through N-th read voltages Vr1′ to Vr7′ to reflect a variation in the threshold voltage distributions of memory cells MCEL. In particular, the read voltage controlling unit may determine the first through N-th read voltages Vr1′ to Vr7′ to reflect variation in threshold voltage distributions corresponding to erase state E and first through seventh program states P1 to P7 of memory cells MCEL. In this way, in operation S300, tracking of some of the first through seventh program states P1 to P7 is performed so that an arithmetic operation for re-determining the first through N-th read voltages Vr1′ to Vr7′ may be performed within a relatively short time. Various examples of operation 300 will be described in further detail with reference to FIGS. 9 through 11.

In operation S400, the memory controller reads the memory device using the determined first through N-th read voltages Vr1′ to Vr7′. In particular, the memory controller reads the data stored in the memory cell array of the memory device by applying the determined first through N-th read voltages Vr1′ to Vr7′ to the memory device.

In operation S500, the memory controller detects an error in the data read from the memory device and corrects the detected error. If no error is detected, the method terminates. In operation S550, the memory controller determines whether the detected error has been corrected. As a result of the determination, if the detected error has been corrected, the method of reading the memory device is terminated, and if the detected error has not been corrected, the method of reading the memory device performs operation S600.

In operation S600, the read voltage controlling unit re-determines first through N-th read voltages Vr1″ to Vr7″ to reflect a variation in threshold voltage distributions of memory cells MCEL. In particular, the read voltage controlling unit re-determines the first through N-th read voltages Vr1″ to Vr7″ to reflect the variation in threshold voltage distributions corresponding to each of erase state E and first through seventh program states P1 to P7 of memory cells MCEL. For example, if the detected error has not been corrected while a second page is read, second, fourth, and sixth read voltages Vr2″, Vr4″, and Vr6″ may be re-determined to reflect a variation in threshold voltage distributions corresponding to each of second, four, and sixth program states P2, P4, and P6. In this way, in operation S600, unlike operation S300, full tracking of first through seventh program states P1 to P7 is performed so that the precision of the re-determined first through N-th read voltages Vr1″ to Vr7″ may be further improved.

In operation S700, the memory controller reads the memory device using the re-determined first through N-th read voltages Vr1″ to Vr7″. In particular, the memory controller reads the data stored in the memory cell array of the memory device by applying the re-determined first through N-th read voltages Vr1″ to Vr7″ to the memory device.

In operation S800, the memory controller detects an error in the data read from the memory device and corrects the detected error. If no error is detected, the method is terminated. In operation S850, the memory controller determines whether the detected error has been corrected. If the detected error has been corrected, the method is terminated, and if the detected error has not been corrected, the method is determined to have failed.

FIG. 9 is a flowchart illustrating an example of operation S300 in the method of FIG. 8 according to an embodiment of the inventive concept. As indicated above, this operation determines first through N-th read voltages Vr1′ to Vr7′. In this example, operation S300 may be referred to as a method of controlling read voltages or a method of varying levels of the read voltages. The method of FIG. 8 may reduce read errors by employing operation S300 of FIG. 9.

Referring to FIG. 9, in operation S310, first read voltage Vr1′ is determined based on a variation in a threshold voltage distribution of memory cells MCEL in erase state E and a variation in a threshold voltage distribution of memory cells MCEL in first program state P1. In some embodiments, operation S310 is performed before operation S320. However, the inventive concept is not limited to this order, and in certain other embodiments, operation S320 can be performed before operation S310.

As described above with reference to FIG. 6B, variations in second and third read voltages Vr2 and Vr3 can be controlled with negative values to decrease second and third read voltages Vr2 and Vr3. On the other hand, variations in first read voltage Vr1 are controlled with positive values so that first read voltage Vr1 is increased. In addition, as described above with reference to FIG. 7B, variations in second through seventh read voltages Vr2 to Vr7 are controlled with negative values so that the second through seventh read voltages Vr2 to Vr7 are decreased. On the other hand, variations in first read voltage Vr1 are controlled with positive values so that first read voltage Vr1 is increased. Thus, first read voltage Vr1 is determined separate from other voltages Vr2 and Vr3, or Vr2 to Vr7 based on a variation in a threshold voltage distribution of memory cells MCEL in erase state E and a variation in a threshold voltage distribution of memory cells MCEL in first program state P1. Although the above description presents an example where the first read voltage Vr1 is increased, aspects of the inventive concept are not limited thereto. For example, in certain other embodiments, first read voltage Vr1 may be decreased.

In general, to determine a first read voltage Vr1′, data may be read from the memory device at each of a plurality of different voltage levels between a threshold voltage in erase state E and a threshold voltage in first program state P1, and a logic operation may be performed with respect to the read data. Subsequently, the number of memory cells in each of a plurality of sections that are distinguished by the plurality of different voltage levels may be counted based on a result of the logic operation to determine a valley between erase state E and first program state P1. A section having a smallest number of memory cells among a plurality of sections may correspond to the valley, and a voltage corresponding to the valley may correspond to the first read voltage Vr1′.

In operation S320, one read voltage among second through N-th read voltages Vr2′ to VrN′ may be determined based on a variation in a threshold voltage distribution of two adjacent program states among first through N-th program states P1 to PN, and the remaining read voltages among second through N-th read voltages Vr2′ to VrN′ may be determined based on one determined read voltage. For example, memory cells MCEL may be 3-bit multi-level cells, and N may be 7. Thus, in operation S320, one among the second through seventh read voltages Vr2′ through Vr7′ may be determined based on the variation in a threshold voltage distribution of two adjacent program states among the first through seventh program states P1 to P7, and the remaining read voltages among the second through seventh read voltages Vr2′ to Vr7′ may be determined based on one determined read voltage.

FIG. 10 is a flowchart illustrating an example of operation S320 in FIG. 9 according to an embodiment of the inventive concept.

Referring to FIG. 10, in operation S3210, an M-th read voltage VrM′ is determined based on variation in a threshold voltage distribution of M-th (where M is a natural number that is equal to or greater than 2) program state PM and variation in a threshold voltage distribution of (M−1)-th program state P(M−1). In this example, M is equal to N, and both M and N are 7. Thus, in operation S3210, a seventh read voltage Vr7′ is determined based on a variation in a threshold voltage distribution of seventh program state P7 and a variation in a threshold voltage distribution of sixth program state P6.

In some embodiments, to determine seventh read voltage Vr7′, data may be read from the memory device at each of a plurality of different voltage levels between a threshold voltage in sixth program state P6 and a threshold voltage in seventh program state P7, and a logic operation may be performed with respect to read data. Subsequently, the number of memory cells in each of a plurality of sections that are distinguished by the plurality of different voltage levels, may be counted based on a result of the logic operation. A result of the counting may determine a valley between sixth program state P6 and seventh program state P7. A section having a smallest number of memory cells among the plurality of sections may correspond to the valley, and a voltage corresponding to the valley may correspond to seventh read voltage Vr7′.

In some embodiments, seventh read voltage Vr7′ is set by applying a pre-determined variation to initial seventh read voltage Vr7, and error detection and correction operations are performed after a read operation is performed using seventh read voltage Vr7′. If a detected error is not corrected, seventh read voltage Vr7′ may be reset by applying a pre-determined variation to the set seventh read voltage Vr7′, and error detection and correction operations may be performed after a read operation is performed using the reset seventh read voltage Vr7′. Seventh read voltage Vr7′ may be determined by performing the above operations repeatedly.

Where memory cells MCEL are in first program state P7, the amount of electrons stored in floating gate FG of memory cell MCEL is larger than where memory cells MCEL are in one among first through sixth program states P1 to P6. Thus, as threshold voltages Vth of memory cells MCEL vary due to an external stimulus applied to memory cells MCEL or wearing, the amount of electrons that leak from floating gate FG is the largest. Thus, a variation in a threshold voltage distribution of seventh program state P7 may be readily checked.

In operation S3220, the remaining read voltages excluding the M-th read voltage VrM′ among second through N-th read voltages may be determined based on the determined M-th read voltage VrM′. In this embodiment, because M is 7, in operation S3220, the second through sixth read voltages Vr2′ to Vr6′ that are the remaining read voltages may be determined based on seventh read voltage Vr7′.

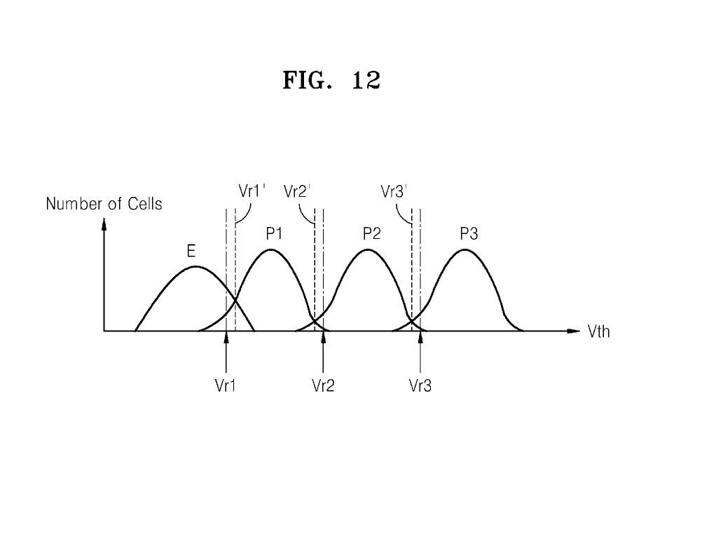

FIG. 11 is a flowchart illustrating an example of operation S3220 in FIG. 10, according to an embodiment of the inventive concept.

Referring to FIG. 11, in operation S32210, a variation ΔVr of a read voltage is determined based on a difference between an initial N-th read voltage VrN and a determined N-th read voltage VrN′. In this embodiment, because M is 7, in operation S32210, the variation ΔVr of the read voltage is determined based on a difference between an initial seventh read voltage Vr7 and a determined seventh read voltage Vr7′. In this case, the determined seventh read voltage Vr7′ is at a lower level than the initial seventh read voltage Vr7, and the variation ΔVr of the read voltage may have a negative value.

In operation S32220, second through (N−1)-th read voltages Vr2′ to Vr(N−1)′ are determined by applying the variation ΔVr to initial second through (N−1)-th read voltages Vr2 to Vr(N−1). In this embodiment, because M is 7, in operation S32220, second through sixth read voltages Vr2 to Vr6 are determined by applying the variation ΔVr to the initial second through sixth read voltages Vr2 to Vr6. Because the variation ΔVr of the read voltage may have a negative value, the initial second through sixth read voltages Vr2 to Vr6 may be decreased.

In the above example, second through seventh read voltages Vr2 to Vr7 are decreased, but the inventive concept is not limited thereto. For example, in alternative embodiments, second through seventh read voltages Vr2 to Vr7 may be increased.

FIG. 12 is a graph illustrating read voltages that have been determined by the operations of FIGS. 9 through 11 for memory cells having the threshold voltage distributions of FIG. 6B.

Referring to FIG. 12, a first read voltage Vr1′ is determined based on a variation in a threshold voltage distribution of erase state E and a variation in a threshold voltage distribution of first program state P1. Thus, the determined first read voltage Vr1′ is increased compared to the initial first read voltage Vr1 and thus may be at a higher level.

In addition, a third read voltage Vr3′ is determined based on a variation in a threshold voltage distribution of third program state P3. A variation ΔVr of a read voltage is determined based on a difference between an initial third read voltage Vr3 and a determined third read voltage Vr3′. A second read voltage Vr2′ is determined by applying the variation ΔVr to the initial second read voltage Vr2.

In this embodiment, because first read voltage Vr1′ is determined separate from second and third read voltages Vr2′ and Vr3′, the chance of a read error occurring in memory cell MCEL in erase state E or first program state P1, may be reduced. In addition, a variation of the third read voltage Vr3 and a variation of the second read voltage Vr2 may be the same based on the determined third read voltage Vr3′. Thus, an arithmetic operation for determining second read voltage Vr2′ may be simplified.

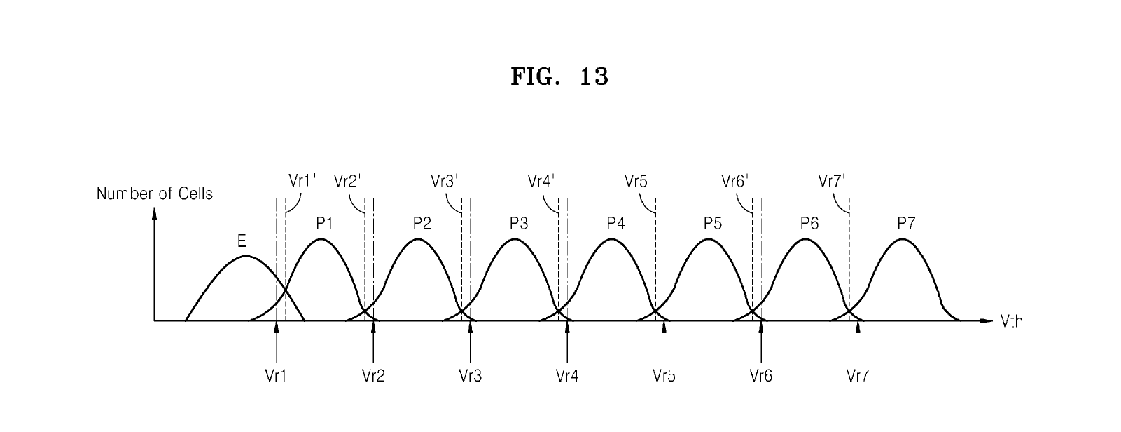

FIG. 13 is a graph illustrating read voltages that have been determined by the operations of FIGS. 9 through 11 for memory cells having the threshold voltage distributions of FIG. 7B.

Referring to FIG. 13, first read voltage Vr1′ is determined based on a variation in a threshold voltage distribution of erase state E and a variation in a threshold voltage distribution of first program state P1. Thus, the determined first read voltage Vr1′ may be increased compared to the initial first read voltage Vr1 and thus may be at a higher level.

In addition, the seventh read voltage Vr7′ is determined based on a variation in a threshold voltage distribution of seventh program state P7. A variation ΔVr of a read voltage is determined based on a difference between the initial seventh read voltage Vr7 and the determined seventh read voltage Vr7′, and second through sixth read voltages Vr2′ to Vr6′ are determined by applying the variation ΔVr to the initial second through sixth read voltages Vr2 to Vr6.

In this embodiment, because the first read voltage Vr1′ is determined separate from second through seventh read voltages Vr2′ to Vr7′, the chance of a read error occurring in memory cell MCEL in erase state E or first program state P1, may be reduced. In addition, a variation of the seventh read voltage Vr7 and variations of the second through sixth read voltages Vr2 to Vr6 may be the same based on the determined seventh read voltage Vr7′. Thus, an arithmetic operation for determining the second through sixth read voltages Vr2′ to Vr6′ may be simplified.

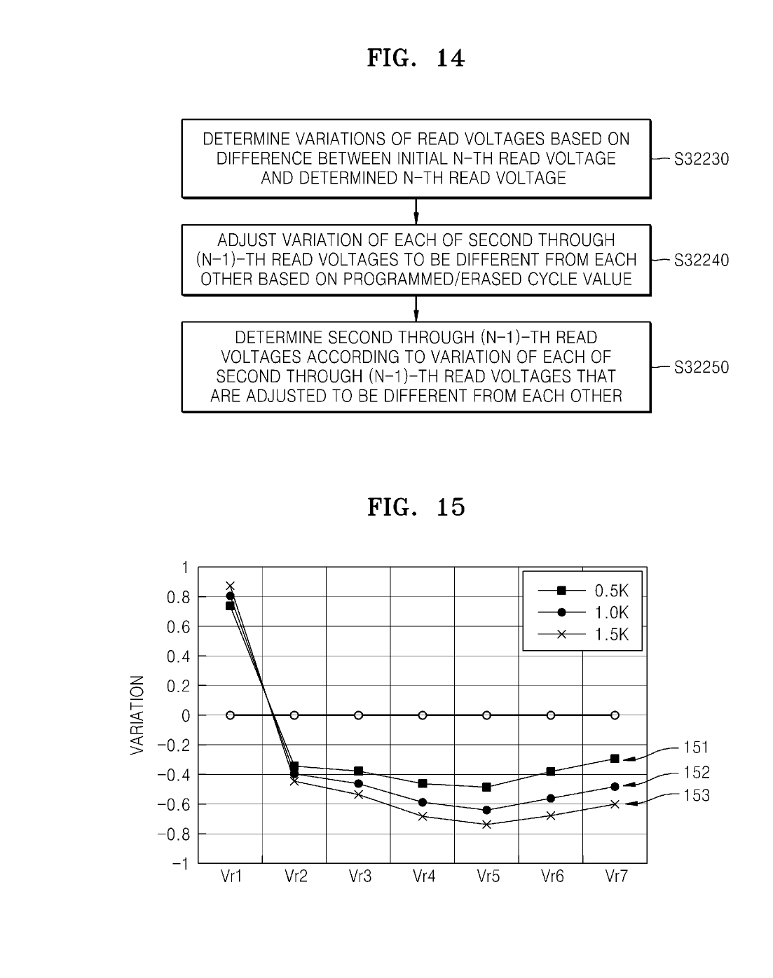

FIG. 14 is a flowchart illustrating an operation determining second through N-th read voltages in the operation of FIG. 9 according to another embodiment of the inventive concept.

Referring to FIG. 14, in operation S32230, a variation ΔVr of a read voltage is determined based on a difference between an initial N-th read voltage VrN and a determined N-th read voltage VrN′. In this embodiment, because M is 7, in operation S32230, the variation ΔVr of the read voltage is determined based on a difference between an initial seventh read voltage Vr7 and a determined seventh read voltage Vr7′. In this case, the determined seventh read voltage Vr7′ is at a lower level than that of the initial seventh read voltage Vr7, and the variation ΔVr of the read voltage has a negative value.

In operation S32240, the variation ΔVr of each of second through (N−1)-th read voltages is adjusted to be different from each other based on a program/erase cycle value. The program/erase cycle value represents the number of program/erase operations that have been performed on memory cell MCEL. In this embodiment, because N is 7, in operation S32240, the variation ΔVr of the second through sixth read voltages is adjusted to be different from each other based on the program/erase cycle value.

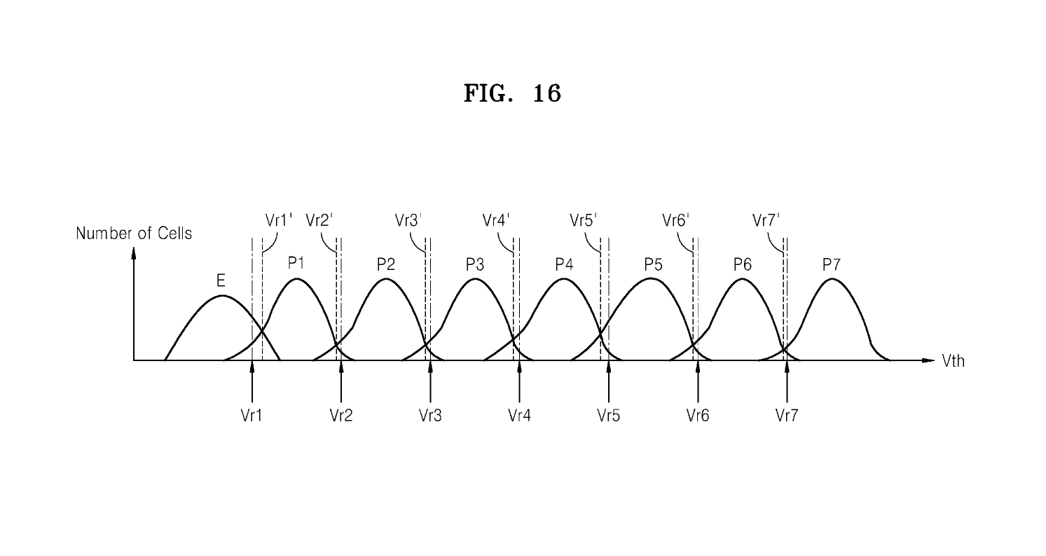

FIG. 15 is a graph showing variations in read voltages according to program/erase cycle values.

Referring to FIG. 15, the horizontal axis represents program states, and the vertical axis represents values obtained by normalizing a difference between an initial read voltage of a memory cell having a program/erase cycle value of 0 (that is, in which a program/erase operation has not been performed) and a varying read voltage. Reference numeral ‘151’ corresponds to an example where the program/erase cycle value is 0.5K, or 500 cycles, and reference numeral ‘152’ corresponds to an example where the program/erase cycle value is 1.0K, that is, 1,000 cycles, and reference numeral ‘153’ corresponds to an example where the program/erase cycle value is 1.5K, or 1,500 cycles.

First, in the example of reference numeral ‘151’, levels of second through seventh read voltages Vr2 to Vr7 are decreased compared to the case where the program/erase cycle value is 0. On the other hand, a level of a first read voltage Vr1 is increased compared to circumstances where the program/erase cycle value is 0. In particular, the level of the first read voltage Vr1 is increased by about 0.7 compared to a situation where the program/erase cycle value is 0, and the levels of the second through seventh read voltages Vr2 to Vr7 are decreased by about 0.3 to about 0.4 compared to a situation where the program/erase cycle value is 0.

Next, in the example of reference numeral ‘152’, the levels of the second through seventh read voltages Vr2 to Vr7 are decreased compared to the case where the program/erase cycle value is 0. On the other hand, the level of the first read voltage Vr1 is increased compared to the case where the program/erase cycle value is 0. In this case, the levels of the second through seventh read voltages Vr2 to Vr7 are further decreased compared to the case where the program/erase cycle value is 0.5K, and the level of the first read voltage Vr1 is further increased compared to the case where the program/erase cycle value is 0.5K. In detail, the level of the first read voltage Vr1 is increased by about 0.8 compared to the case where the program/erase cycle value is 0, and the levels of the second through seventh read voltages Vr2 to Vr7 are decreased by about 0.4 to about 0.6 compared to the case where the program/erase cycle value is 0.

Next, in the example of reference numeral ‘153’, the levels of the second through seventh read voltages Vr2 to Vr7 are decreased compared to the case where the program/erase cycle value is 0, and the level of the first read voltage Vr1 is increased compared to circumstances where the program/erase cycle value is 0. In this example, the levels of the second through seventh read voltages Vr2 to Vr7 are further decreased compared to circumstances where the program/erase cycle value is 1.0K, and the level of the first read voltage Vr1 is further increased compared to the case where the program/erase cycle value is 1.0K. In detail, the level of first read voltage Vr1 is increased by about 0.9 compared to circumstances where the program/erase cycle value is 0, and the levels of the second through seventh read voltages Vr2 to Vr7 are decreased by about 0.4 to about 0.7 compared to circumstances where the program/erase cycle value is 0.

In this way, the levels of the read voltages for reading program states may vary according to the program/erase cycle value. Accordingly, variations of the levels of the read voltages in the program states may be different from each other.

Referring again to FIG. 14, in operation S32240, the variation ΔVr of each of the second through (N−1)-th read voltages is adjusted to be different from each other to reflect the graph of FIG. 15. In particular, as the program/erase cycle value is increased, the variation ΔVr of each of the second through (N−1)-th read voltages may be adjusted to be large. In addition, the variation ΔVr of each of the second through (N−1)-th read voltages is adjusted to be different from each other in such a way that the variation ΔVr of the fifth read voltage for reading fifth program state P5 is the largest.

In operation S32250, second through (N−1)-th read voltages Vr2′ to Vr(N−1)′ are determined according to the variation ΔVr of each of second through (N−1)-th read voltages that is adjusted to be different from each other. In this embodiment, because N is 7, in operation S32250, second through sixth read voltages Vr2′ to Vr6′ are determined according to the variation ΔVr of each of second through sixth read voltages Vr2′ to Vr6′.

FIG. 16 is a graph of read voltages that have been determined by the operation of FIG. 14 for memory cells having the threshold voltage distributions of FIG. 7B.

Referring to FIG. 16, first read voltage Vr1′ is determined based on a variation in a threshold voltage distribution of erase state E and a variation in a threshold voltage distribution of the first program states P1. Thus, the determined first read voltage Vr1′ is increased compared to an initial first read voltage Vr1 and thus is at a higher level.

In addition, seventh read voltage Vr7′ is determined based on a variation in a threshold voltage distribution of seventh program state P7. A variation ΔVr of a read voltage is determined based on a difference between an initial seventh read voltage Vr7 and the determined seventh read voltage Vr7′. Subsequently, the variation ΔVr of each of the second through sixth read voltages is adjusted to be different from each other based on a program/erase cycle value. Second through sixth read voltages Vr2′ to Vr6′ are determined based on the variation ΔVr of each of the second through sixth read voltages.

In this embodiment, because first read voltage Vr1′ is determined separate from the second through seventh read voltages Vr2′ to Vr7′, the chance of a read error occurring in memory cell MCEL in erase state E or first program state P1, may be reduced. In addition, the variation ΔVr of each of second through sixth read voltages Vr2 to Vr6 may be adjusted to be different from each other, based on the program/erase cycle value. Thus, precision of second through sixth read voltages Vr2′ to Vr6′ may be further improved.

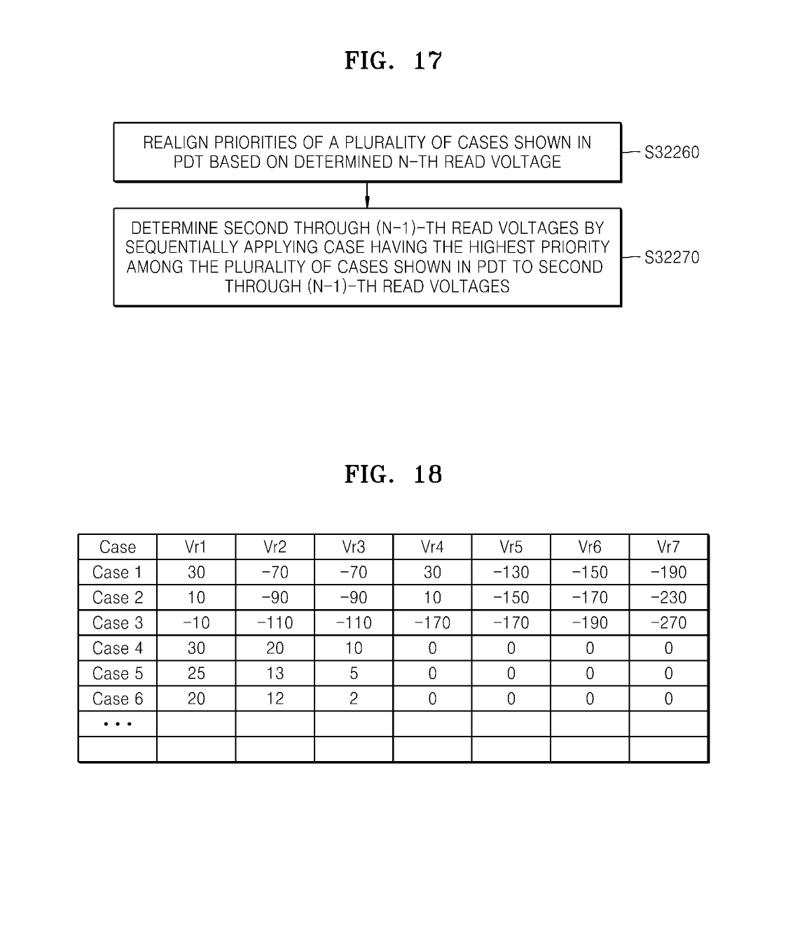

FIG. 17 is a flowchart illustrating an operation determining second through N-th read voltages in the operation of FIG. 9 according to another embodiment of the inventive concept.

Referring to FIG. 17, in operation S32260, priorities of a plurality of cases shown in a pre-defined table (PDT) are realigned based on a determined N-th read voltage VrN′. In particular, a case having a variation closest to a variation of a determined N-th read voltage among the plurality of cases shown in the PDT is realigned with a highest priority based on a difference between an initial N-th read voltage VrN and the determined N-th read voltage.

In operation S32270, second through (N−1)-th read voltages Vr2′ to Vr(N−1)′ are determined by sequentially applying the case having the highest priority among the plurality of cases shown in the PDT to the second through (N−1)-th read voltages Vr2′ to Vr(N−1)′. In this way, a read success rate of the memory device may be improved within a short time compared to randomly applying all of the cases to the second through (N−1)-th read voltages Vr2′ to Vr(N−1)′ by applying the cases shown in the PDT to the second through (N−1)-th read voltages Vr2′ to Vr(N−1)′ according to their priorities.

FIG. 18 is a table illustrating an example of the PDT used in the operation of FIG. 17.

Referring to FIG. 18, the PDT shows variations of first through seventh read voltages Vr1 to Vr7 that are pre-defined according to program states in each of a plurality of cases Case 1 through Case 6. For example, first case Case1 occurs where a charge loss of a memory cell occurs due to long-term leaving the memory device. In this case, distributions of program states may vary so as to decrease threshold voltages. A first read voltage Vr1 is increased by about 30 mV; second and third read voltages Vr2 and Vr3 are decreased by about 70 mV; fourth and fifth read voltages Vr4 and Vr5 are reduced by about 130 mV; a sixth read voltage Vr6 is reduced by about 150 mV; and a seventh read voltage Vr7 is reduced by about 190 mV. In this way, the variations of the first through seventh read voltages Vr1 to Vr7 are increased as they gets closer to a seventh program state P7.

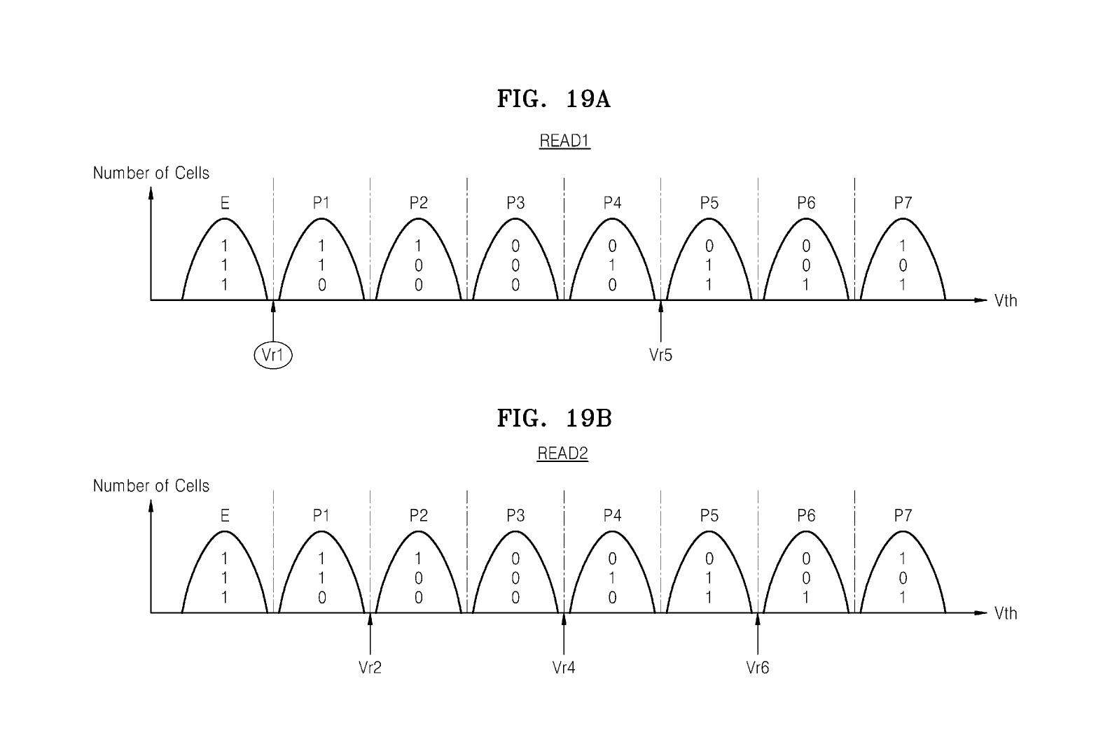

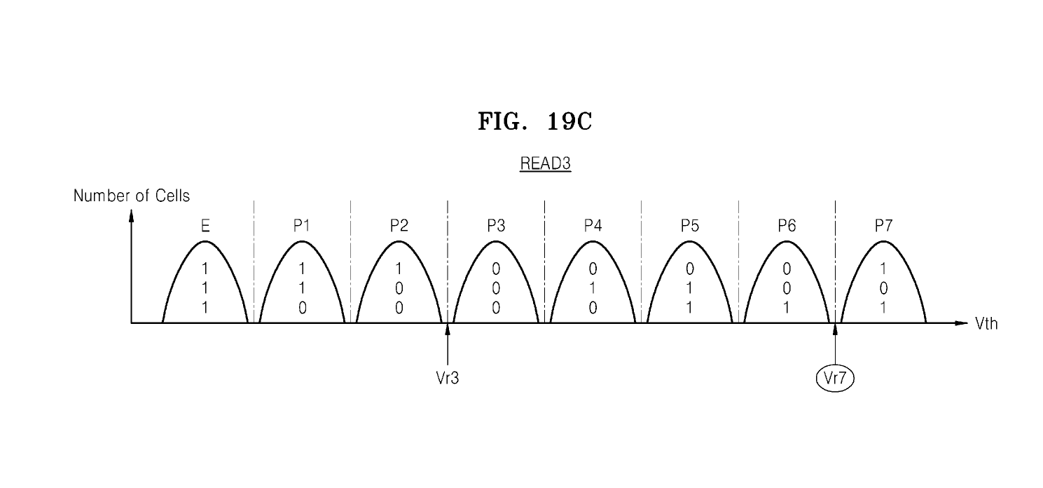

FIGS. 19A through 19C are graphs showing read orders per page for illustrating the operations illustrated in FIGS. 8 through 11, FIG. 14, and FIG. 17.

Referring to FIGS. 19A through 19C, data ‘111’ is assigned to an erase state E, data ‘110’ is assigned to a first program state P1, data ‘100’ is assigned to a second program state P2, data ‘000’ is assigned to a third program state P3, data ‘010’ is assigned to a fourth program state P4, data ‘011’ is assigned to a fifth program state P5, data ‘001’ is assigned to a sixth program state P6, and data ‘101’ is assigned to a seventh program state P7.

Where memory cell MCEL is a 3-bit multi-level cell that is programmed with 3 bits, three logic pages are stored in one physical page. Here, a logic page represents a set of data that is simultaneously programmed in one physical page. Thus, three read operations are sequentially performed on one physical page including memory cell MCEL. In this case, the order of performing three read operations is changed according to the data allocated to erase state E and first through seventh program states P1 to P7.

In this embodiment, a first read operation READ1, which is a least significant bit (LSB) read operation, is performed between erase state E in which the LSB varies and first program state P1 and between fourth program state P4 and fifth program state P5, as illustrated in FIG. 19A. In this way, in first read operation READ 1, a read operation is performed twice.

A second read operation READ2, which is a central significant bit (CSB) read operation, is performed between first program state P1 in which the CSB varies and second program state P2, between third program state P3 and fourth program state P4, and between fifth program state P5 and sixth program state P6, as illustrated in FIG. 19B. In this way, in second read operation READ2, a read operation is performed three times.

A third read operation READ3, which is a most significant bit (MSB) read operation, is performed between second program state P2 in which the MSB varies and third program state P3 and between sixth program state P6 and seventh program state P7, as illustrated in FIG. 19C. In this way, in third read operation READ3, a read operation is performed twice.

In operation S310 for determining first read voltage Vr1 of the operations illustrated in FIGS. 8 through 11, FIG. 11, and FIG. 17 is performed in the first read operation READ1, and operation S3210 for determining the seventh read voltage Vr7 is performed in third read operation READ3. In this case, in first read operation READ1 and the third read operation READ3, a read operation is performed twice, and in second read operation READ2, a read operation is performed three times. In this way, because the number of reads of the first read operation READ1 and the number of reads of third read operation READ3 are smaller than the number of reads of second read operation READ2, there is a relatively low chance that an error will occur in the operation S310 of determining the first read voltage Vr1 and the operation S3210 of determining the seventh read operation Vr7.

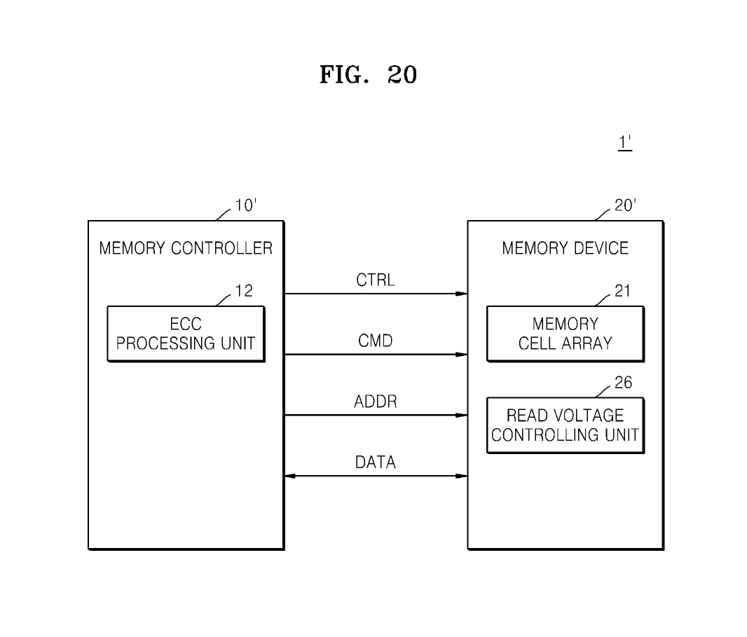

FIG. 20 is a block diagram of a memory system 1′ according to another embodiment of the inventive concept.

Referring to FIG. 20, memory system 1′ comprises a memory controller 10′ and a memory device 20′. Some of elements of memory system 1′ are substantially the same as those of memory system 1 of FIG. 1, and the following description will focus on differences between memory system 1′ of FIG. 20 and memory system 1 of FIG. 1.

Memory device 20′ comprises a memory cell array 21 and a read voltage controlling unit 26. Memory cell array 21 comprises a plurality of memory cells (not shown) disposed at intersections of wordlines and bitlines. Read voltage controlling unit 26 controls levels of read voltages for reading data stored in memory cells of memory cell array 21.

Memory controller 10′ comprises an ECC processing unit 12. ECC processing unit 12 checks whether an error, i.e., a read error exists in data read from memory device 20, and it corrects the error.

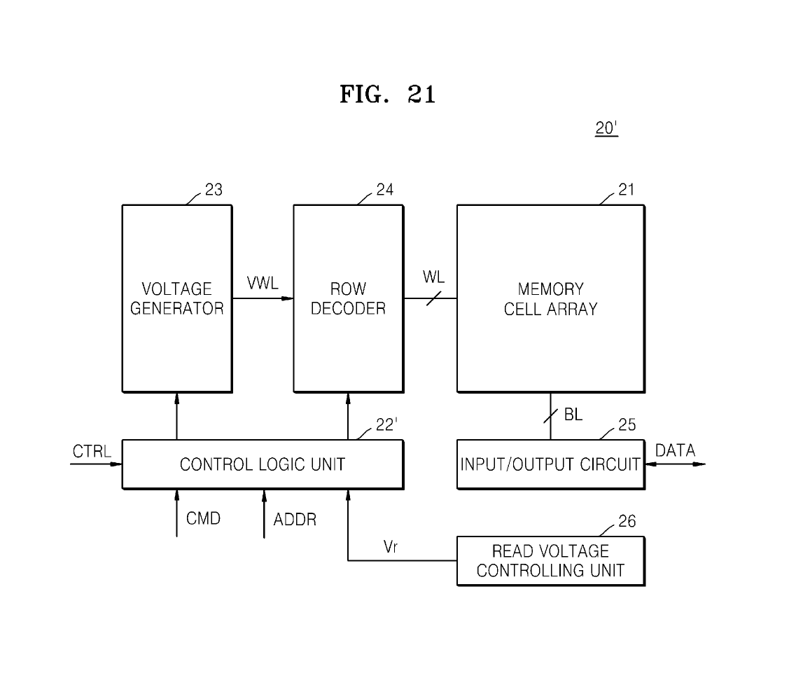

FIG. 21 is a block diagram of memory device 20′ in memory system 1′ of FIG. 20, according to another embodiment of the inventive concept.

Referring to FIG. 21, memory device 20′ comprises a memory cell array 21, control logic unit 22′, a voltage generator 23, a row decoder 24, an input/output circuit 25, and a read voltage controlling unit 26. Some features of memory device 20′ are substantially the same as those of memory device 20 of FIG. 2. Like reference numerals refer to like elements, and descriptions of the elements of memory device 20′ of FIG. 21 that are the same as those of memory device 20 of FIG. 2, will not be provided. Hereinafter, differences between memory device 20′ of FIG. 21 and memory device 20 of FIG. 2 will be described.

Control logic unit 22′ outputs various control signals for writing data to memory cell array 21 or for reading the data from memory cell array 21 based on command signals CMD, address signals ADDR, and control signals CTRL, which are received from memory controller 10, and read voltages Vr received from read voltage controlling unit 26. In this case, the control signals output from control logic unit 22′ are transferred to voltage generator 23, row decoder 24, and input/output circuit 25.

Read voltage controlling unit 26 controls levels of the read voltages Vr for reading the data stored in memory cells of memory cell array 21. Outputs from read voltage controlling unit 26, for example, controlled read voltages Vr or variations of read voltages Vr are provided to control logic unit 22′. In this way, memory device 20′ includes read voltage controlling unit 26. Thus, read voltage controlling unit 26 controls levels of read voltages Vr based on threshold voltages that have varied due to an external stimulus and/or wear. Thus, an RBER of the memory device may be improved.

Memory system 1 of FIG. 1 or memory system 1′ of FIG. 20 can be combined with an application chipset, a camera image processor, a mobile DRAM, or the like and may be provided as a storage device for an information processing apparatus that may exchange high-capacity data.

Memory device 20 of FIG. 1, or memory device 20′ of FIG. 20 and memory system 1 of FIG. 1, or memory system 1′ of FIG. 20 may be mounted using packages having various shapes. For example, memory device 20 of FIG. 1, or memory device 20′ of FIG. 20 and memory system 1 of FIG. 1, or memory system 1′ of FIG. 20 may be mounted using packages, such as Package on Package (POP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

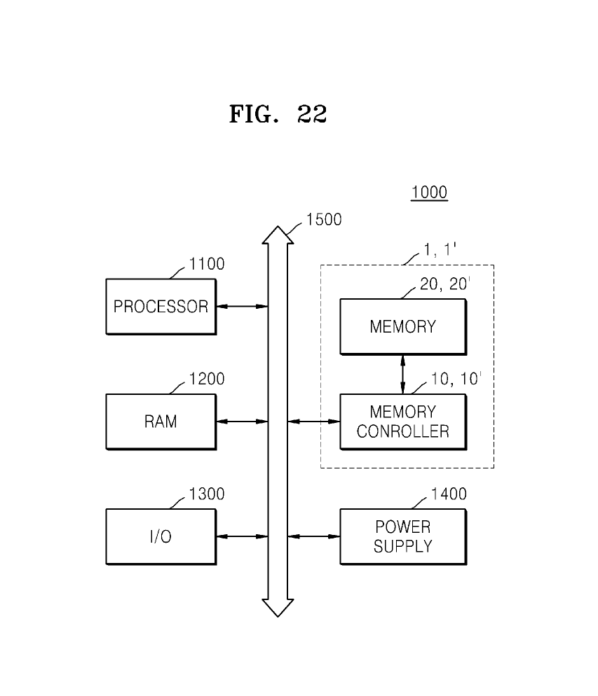

FIG. 22 is a block diagram of a computing system 1000 incorporating the memory system of FIG. 1 or 20, according to an embodiment of the inventive concept.

Referring to FIG. 22, computing system 1000 comprises a processor 1100, a RAM 1200, an input/output device 1300, a power supply device 1400, and memory systems 1 and 1′. Although not shown, computing system 1000 may further comprise ports that may communicate with video cards, sound cards, memory cards, universal serial bus (USB) devices, or other electronic devices. Computing system 1000 can be implemented as a personal computer (PC), or a portable electronic device, such as a notebook computer, a mobile phone, a personal digital assistant (PDA), a camera, or the like.

Processor 1100 can perform pre-determined calculations or tasks. In one embodiment, processor 1100 may be a micro-processor or a central processing unit (CPU). Processor 1100 may perform communication with RAM 1200, input/output device 1300, and memory systems 1 and 1′ via an address bus, a control bus, a databus, or the like. In one embodiment, processor 1100 may be connected to an extension type computer bus, such as a Peripheral Component Interconnect (PCI) bus.

RAM 1200 stores data required for an operation of computing system 1000. For example, memory device 1200 may be implemented with a DRAM, a mobile DRAM, an SRAM, a PRAM, an FRAM, an RRAM and/or an MRAM.

Input/output device 1300 comprises an input unit, such as a keyboard, a keypad, a mouse, or the like, and an output unit, such as a printer, a display, or the like. Power supply device 1400 may supply operating voltages required for the operation of computing system 3000.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept.

Accordingly, all such modifications are intended to be included within the scope of the inventive concept as defined in the claims.

What is claimed is:

1. A method of reading a memory device comprising a memory cell that is in one of an erase state and first through N-th program states (N>2), the method comprising:
determining a first read voltage between the erase state and the first program state based on variations of respective threshold voltage distributions of the erase state and the first program state; and
determining one among second through N-th read voltages based on variations in respective threshold voltage distributions of two adjacent program states among the first through N-th program states, and determining remaining read voltages among the second through N-th read voltages based on the one read voltage.

2. The method of claim 1, wherein determining the second through N-th read voltages comprises:
determining an M-th read voltage (1<M<N+1), between an (M−1)-th program state and an M-th program state, based on variations respective threshold voltage distributions of the M-th and (M−1)-th program states, wherein the M-th and (M−1)-th program states are among the first through N-th program states and the M-th read voltage is the one among the second through N-th read voltages; and
determining the remaining read voltages based on the M-th read voltage.

3. The method of claim 1, wherein determining second through N-th read voltages comprises:
determining an N-th read voltage between a (N−1)-th program state and an N-th program state based on a variation in a threshold voltage distribution of the N-th program state and a variation in a threshold voltage distribution of the (N−1)-th program state; and
determining the second through (N−1)-th read voltages based on the N-th read voltage.

4. The method of claim 3, wherein determining second through (N−1)-th read voltages comprises:
determining variations between read voltages based on a difference between an initial N-th read voltage and the determined N-th read voltage; and
determining the second through (N−1)-th read voltages by applying the variations to initial second through (N−1)-th read voltages.

5. The method of claim 3, wherein determining the second through (N−1)-th read voltages comprises determining the second through (N−1)-th read voltages based on the determined N-th read voltage and a program/erase cycle value of the memory cell.

6. The method of claim 5, wherein determining the second through (N−1)-th read voltages comprises:
determining variations of read voltages based on a difference between an initial N-th read voltage and the determined N-th read voltage;
adjusting the variations of the second through (N−1)-th read voltages to be different from each other based on the program/erase cycle value; and
determining the second through (N−1)-th read voltages according to the variations of the second through (N−1)-th read voltages that are adjusted to be different from each other.

7. The method of claim 3, wherein determining the N-th read voltage is performed in a page read operation having a relatively small number of reads among sequential page read operations of the memory device.

8. The method of claim 1, wherein determining of the first read voltage is performed in a page read operation having a relatively small number of reads among sequential page read operations of the memory device.

9. The method of claim 1, further comprising:
reading the memory device by using the determined first through N-th read voltages; and
detecting an error from the read memory device and correcting the detected error.

10. The method of claim 9, further comprising:
re-determining the first through N-th read voltages based on a variation in a threshold voltage distribution of the erase state and each of the first through N-th program states according to a result of correcting the detected error;
reading the memory device by using the re-determined first through N-th read voltages; and
re-detecting an error from the read memory device and recorrecting the re-detected error.

11. The method of claim 1, further comprising:
reading the memory device using initial first through seventh read voltages; and
selectively detecting an error from the read memory device and correcting the detected error, or performing the determining of the first read voltage and the determining of the second through N-th read voltages upon determining that the detected error cannot be corrected.

12. The method of claim 1, wherein a level of the determined first read voltage is increased compared to an initial first read voltage, and levels of the determined second through N-th read voltages are decreased compared to initial second through N-th read voltages.

13. The method of claim 1, wherein the N-th program state corresponds to a higher threshold voltage of the memory cell compared to the erase state.

14. A memory device, comprising:
a memory cell array comprising a plurality of memory cells each being in one among an erase state and first through N-th program states (N>2); and
a read voltage controlling unit that determines a first read voltage between the erase state and the first program state based on respective variations of threshold voltage distributions of the erase state and the first program state, determines one among second through N-th read voltages based on respective variations in threshold voltage distributions of two adjacent program states among the first through N-th program states, and determines remaining read voltages among the second through N-th read voltages based on the one read voltage.

15. The memory device of claim 14, wherein the read voltage controlling unit determines an N-th read voltage between a (N−1)-th program state and an N-th program state based on respective variations in threshold voltage distributions of the N-th program state and the (N−1)-th program state and determines the second through (N−1)-th read voltages based on the N-th read voltage.

16. The memory device of claim 15, wherein the read voltage controlling unit determines the second through (N−1)-th read voltages based on the determined N-th read voltage and a program/erase cycle value of the plurality of memory cells.

17. A method of reading a memory device comprising a memory cell that is in one of an erase state and first through N-th program states (N>2), the method comprising:
determining one among first through N-th read voltages for the memory cell based on data read from the memory device, and determining additional read voltages among the second through N-th read voltages based on the one read voltage.

18. The method of claim 17, further comprising, determining a first read voltage between the erase state and the first program state independent of determining second through N-th read voltages.

19. The method of claim 17, wherein determining the one among the first through N-th read voltages comprises determining an initial read voltage, and determining an adjustment value for the initial read voltage based on the data read from the memory device.

20. The method of claim 19, further comprising determining the additional read voltages by applying the determined adjustment value to additional initial read values.
